(19) United States
(12) Patent Application Publication
(10) Pub. No.: US 2012/0285627 A1
(43) Pub. Date: Nov. 15, 2012

(54) Elastomer Bonded Item and Method for Debonding

(75) Inventors: Ryan A. Scatena, Gilroy, CA (US); Wayne R. Simpson, San Jose, CA (US)

(73) Assignee: THERMAL CONDUCTIVE BONDING, INC., San Jose, CA (US)

(21) Appl. No.: 13/466,890

(22) Filed: May 8, 2012

Related U.S. Application Data
(60) Provisional application No. 61/484,456, filed on May 10, 2011.

(51) Int. Cl. B32B 7/04; B32B 38/10; B32B 18/00; C23C 14/34; B32B 15/04; B32B 27/00

(52) U.S. Cl. 156/711; 428/457; 428/672; 428/656; 428/450; 428/447; 204/298.13

(57) ABSTRACT

An item, such as a sputtering target assembly or an electrostatic chuck, comprised of a first substrate; a metallization layer adhered to a surface of the first substrate; a second substrate; and an elastomer layer positioned between the metallization layer and the second substrate. In another embodiment, a debonding layer, such as a solder material, is positioned between the elastomer layer and the second substrate for allowing the item to be disassembled after use by heating the item up to the approximate melting point of the debonding layer.

This application claims the benefit of U.S. provisional application 61/484,456, filed May 10, 2011, which is incorporated herein by reference.

### BACKGROUND OF THE INVENTION

The use of elastomeric materials to attach components together is well known in the art, particularly in the semiconductor manufacturing industry. For example, U.S. Pat. No. 6,194,322 describes an electrode for use in a plasma reaction chamber that is bonded to a support member using an elastomer. Similarly, U.S. published patent application number US 2006/0272941 A1 (published Dec. 7, 2006), describes a methodology for manufacturing large area sputtering target assemblies in which the sputtering target is held to the backing plate with an elastomer. As new semiconductor manufacturing processes are developed, improvements in elastomer bonding technology are needed.

### SUMMARY OF THE INVENTION

Briefly, the present invention comprises an item, such as a sputtering target assembly, a showerhead electrode or an electrostatic chuck, comprised of a first substrate; a metallization layer adhered to a surface of the first substrate; a second substrate; and an elastomer layer positioned between the metallization layer and the second substrate. The use of the metallization layer improves the bond between the first substrate and the elastomer layer.

In another embodiment, a debonding layer is positioned between the elastomer layer and the second substrate for allowing the item to be disassembled after use by heating the item up to the approximate melting point of the debonding layer. Generally, the debonding layer comprises a material having a melting point in the range of 75 to 250° C. The preferred material for use in the debonding layer 46 is a solder material, such as indium, tin, bismuth, and solder alloys containing these materials.

### BRIEF DESCRIPTION OF THE SEVERAL VIEWS OF THE DRAWINGS

FIG. 1 is a cross-sectional view of an elastomer bonded item according to the present invention; and

FIG. 2 is cross-sectional view of an elastomer bonded item that includes a debonding layer according to the present invention.

### DETAILED DESCRIPTION OF THE INVENTION

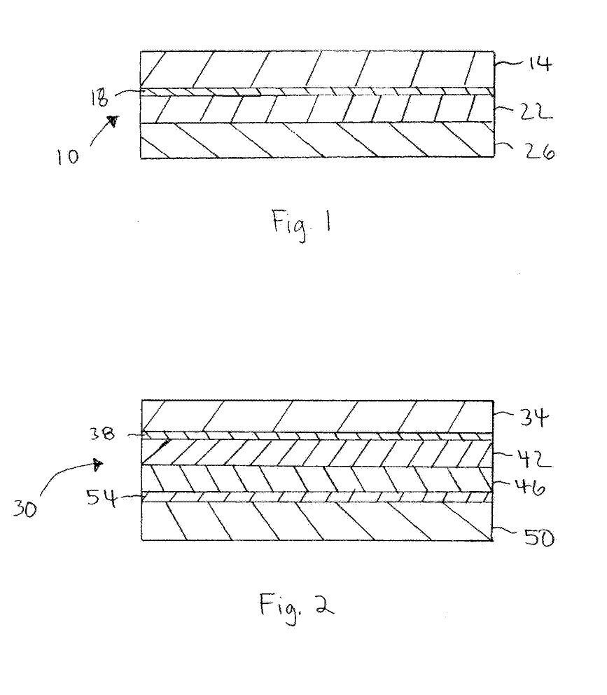

FIG. 1 illustrates an item 10 that comprises a substrate 14, a metallization layer 18, an elastomer layer 22 and a substrate 26. In many situations, the substrates 14 and 26 must be strongly bonded together without gaps in the layer or layers that hold the substrates 14 and 26 together. Such gaps could, for example, weaken the bond or provide a pathway for electrical arcing, or for the passage of gases or fluids, between the substrates 14 and 26.

In the present invention, the substrate 14 is comprised of a material that for some reason does not form a satisfactory bond directly with the elastomer layer 22. The unsatisfactory bond may result from insufficient adhesion between the substrate 14 and the elastomer layer 22, from the formation of gaps between the substrate 14 and the elastomer layer 22, or for other reasons. To improve the quality of the bond between the substrate 14 and the elastomer layer 22, the metallization layer 18 is interposed between the substrate 14 and the elastomer layer 22.

In a preferred embodiment, the metallization layer 18 is applied to a surface of the substrate 14 before the substrates 14 and 26 are bonded together. The elastomer layer 22 is then applied between the metallization layer 18 (which is now part of the substrate 14) and the substrate 26. The elastomer is allowed to cure before the item 10 is ready for use.

The substrate 14 can be comprised of any material that does not form a satisfactory bond directly with the elastomer layer 22 and could be used for any purpose. For example, representative materials that can be used as the substrate 14 include gold or a ceramic material. Representative functions for the substrate 14 after the item 10 is formed include sputtering targets, showerhead electrodes and electrostatic chucks.

The metallization layer 18 can be comprised of many metals, such as aluminum, titanium, chrome, nickel, copper or solder materials, such as indium, tin, bismuth, and solder alloys containing these materials. The metallization layer 18 can be applied to the substrate 14 by any suitable technique, such as sputtering, plating anodizing or ultrasonic wetting.

The elastomer layer 22 can be comprised of many types of elastomers. In general, an elastomer is a substance (preferably a polymer) having elastic properties. Preferred types of elastomers that can be used in the elastomer layer 22, include a silicone elastomer or a poly(dimethylsiloxane) elastomer, such as Sylgard® 184 brand silicone elastomer sold by Dow Corning. Poly(dimethylsiloxane) elastomer (PDMS) is a silicone elastomer comprised of a Si—O—Si backbone with each silicon atom bearing two methyl (Me) groups. PDMS is typically denoted as (Me₂SiO)ₙ.

Other types of elastomers that can be used in the elastomer layer 22 are the fluoroelastomers referred to as FKMs (also known as FPMs) and the perfluoroelastomers referred to as FFKMs (also known as FFPMs). FKMs are copolymers that contain monomer units of vinylidene fluoride (CH₂═CF₂) and a comonomer, such as hexafluoropropylene (HFP), tetrafluoroethylene (TFE), perfluoromethylvinylether (PMVE), propylene or ethylene. FKMs have very good resistance to heat and chemicals and are sold commercially under trademarks such as Viton™, Dai-EI™,Dyneon™ and Tecnoflon™.

FFKMs are terpolymers comprised of tetrafluoroethylene (CF₂═CF₂), and usually PMVE and another monomer. Because FFKMs are highly fluorinated polymers, they have exceptionally good resistance to chemicals along with the elastic properties of FKMs. FFKMs are sold commercially under trademarks such as Chemraz™ and Kalrez™.

Additional types of suitable elastomers that can be used as the elastomer layer 22 include polyimide, polyketone, polyetherketone, polyether sulfone, polyethylene terephthalate, and fluroethylene propylene copolymers. Flexible epoxy or rubber can also be used Other silicone elastomers that can be used include the products marketed as General Electric RTV 31 and General Electric RTV 615 brand silicone elastomers.

The substrate 26 can be comprised of any suitable material that bonds directly with the elastomer layer 22 and can be used for any purpose. Representative functions for the substrate 26 after the item 10 is formed include backing plates and/or cooling plates. Aluminum is a preferred material for the substrate 26.

In a representative example, the item 10 is a sputtering target assembly used to deposit thin films on objects like semiconductor devices, glass or other substrates requiring a thin film. The substrate 14 is a sputtering target comprised of gold, the metallization layer 18 comprises titanium and aluminum applied to the backside of the substrate layer 14 by sputtering. The elastomer layer 22 comprises the. PDMS elastomer, such as the elastomer sold by Dow Corning under the product name/designation Sylgard® 184. The substrate 26 is a backing plate comprised of copper which is cooled with water during use. The use of the metallization layer 18 improves the bond with the elastomer layer 22 so that delamination does not occur between the substrate 14 and 26 during the sputtering process.

The PDMS elastomer in the elastomer layer 22 may be applied between the substrate 14 and the substrate 26 using any suitable procedure. For example, U.S. published patent application number US 2006/0272941 A1 (published Dec. 7, 2006), which is incorporated herein by reference, describes how a sputtering target can be attached to a backing plate using an elastomer layer comprised of Sylgard® 184. In a representative embodiment of the present invention, the Sylgard® 184 PDMS elastomer in the elastomer layer 22 is applied between the metallization layer 18 and the substrate 26 using the following procedure:

The surfaces of the metallization layer 18 and the substrate 26 that will be in contact is with the elastomer layer 22 are primed to promote adhesion with the elastomer to the layer 18, such as by coating the surfaces with Dow Corning Primer 1200, or a similar chemical. At this time, a piece of copper mesh (i.e. copper screen) is primed, for example by coating the surface of the copper mesh with Dow Corning Primer 1200, or a similar chemical. The copper mesh is cut to size so that it is approximately 0.100 inches shorter than the substrate 14 in both length and width directions.

After the recommended wait time for allowing the primer to dry, the Sylgard® 184is mixed according to the manufacturer's instructions. Aluminum powder filler is added to the elastomer in a ratio of 1:1 by weight of the A component of elastomer (Sylgard® 184). The elastomer/aluminum powder mixture is thoroughly mixed and degassed in a vacuum degassing chamber to remove air bubbles. The elastomer mixture is then uniformly applied to the surfaces of the metallization layer 18 and the substrate 26 that were previously primed.

The piece of primed copper mesh is then placed on the elastomer that is covering the substrate 26. The substrate 14 is then placed on the substrate 26 with the elastomer coated on the metallization layer 18 being brought into contact with the elastomer coated on the substrate 26. Pressure is applied to the substrate 14 to hold the item 10 together while the elastomer cures, such as by applying four pounds per square inch (PSI) on the substrate 14, either by weight or clamping. Heat is then applied to the item 10 to cure the elastomer. Generally, the conditions needed to cure the elastomer (such as temperature and time) are specified by the manufacturer of the elastomer. After the elastomer has cured, the pressure is removed and the elastomer bond is sufficiently strong to hold the item 10 together in a plasma environment, such as the environment that exists inside a plasma etch chamber.

The purpose of the aluminum powder and the piece of copper mesh inserted into the elastomer layer is to facilitate the transfer of heat from the substrate 14 to the substrate 26. In some embodiments, the copper mesh and/or the aluminum powder is not needed and one or both of these components can be deleted.

In one embodiment, the present invention is an item comprised of a first substrate (such as the substrate 14); a metallization layer (such as the metallization layer 18) adhered to a surface of the first substrate; a second substrate (such as the substrate 26); and an elastomer layer (such as the elastomer layer 22) positioned between the metallization layer and the second substrate. The first substrate and the second substrate are held together by the elastomer layer without the need for additional attachment means to hold the first substrate and the second substrate together. The elastomer layer is sufficiently strong to hold the first substrate and the second substrate together in a plasma environment, such as the environment that exists inside a plasma etch chamber.

Referring to FIG. 1, in many situations, at some point after the item 10 (has been formed, there is a need to take the substrates 14 and 26 apart (i.e. to debond the item 10). Debonding might be necessary to replace or repair one of the substrates 14 or 26 or for some other reason. However, since the elastomers used in the elastomer layer 22 have fairly high failure points (e.g. >250° C.), it is frequently not desirable to heat the item 10 up to a temperature where the elastomer will fail because high temperatures may damage one or both of the substrates 14 or 26. A solution to this problem is illustrated in FIG. 2.

FIG. 2 illustrates an item 30 that comprises a substrate 34, a metallization layer 38, an elastomer layer 42, a debonding layer 46 and a substrate 50. In some embodiments, a wetting or metallization layer 54 is positioned between the substrate 50 and the debonding layer 46 to help the debonding layer 46 better adhere to the substrate 50. However, use of the layer 54 is optional. Use of the debonding layer 46 provides a method for debonding substrates 34 and 50, meaning that the substrates 34 and 50 can he separated from each other. In a preferred embodiment, the debonding layer 46 comprises a material with a relatively low melting point. Since the materials used in the debonding layer 46 melt at lower temperatures (e.g. 75 to 250° C.) than the elastomer layer 42, the item 30 can be debonded (taken apart) by heating to the temperature where the material in the debonding layer melts or ceases to hold the item 30 together. Once the substrates 34 and 50 have been separated, the elastomer layer 42 can be removed, for example, by scraping the elastomer off of the substrate 34 if this is desired.

In FIG. 2, the substrate 34 is analogous to the substrate 14 described previously with respect to FIG. 1, meaning that the materials and/or functions described previously for the substrate 14 apply to the substrate 34. Similarly, the metallization layer 38, the elastomer layer 42 and the substrate 50 shown in FIG. 2 are analogous to the metallization layer 18, the elastomer layer 22 and the substrate 26, respectively, shown in FIG. 1.

The debonding layer 46 comprises any suitable low melting material, and preferably has a melting point in the range of 75 to 250° C., and more preferably in the range of 75 to 232° C. However, the preferred material for use in the debonding layer 46 is a solder material. Any suitable solder material can be used, but solder materials such as indium, tin, bismuth, and solder alloys containing these materials are preferred for use in the debonding layer 46.

In a representative example, the item 30 is an electrostatic chuck assembly. The. substrate 34 comprises an electrostatic chuck (ESC) used to hold a semiconductor wafer in place during processing. The electrostatic chuck comprises a ceramic material such as aluminum oxide. The metallization layer 38 comprises titanium and aluminum applied to the backside of the substrate 34 by sputtering. The debonding layer 46 comprises tin and the elastomer layer 42 comprises a PDMS elastomer, such as the elastomer sold by Dow Coming under the product name/designation Sylgard® 184. The substrate 50 is a cooling plate comprised of aluminum. The use of the metallization layer 38 improves the bond between the substrate 34 and the elastomer layer 42. The wetting layer 54 is comprised of tin and helps the debonding layer 46 adhere to the substrate 50. The debonding layer 46 allows the substrate 34 to be separated from the substrate 50 by heating the item 30 to a temperature that does not damage the substrates 34 and/or 50.

The item 30 is assembled using the following procedure: The metallization layer 38 (titanium and aluminum) is applied to a backside surface of the substrate 34 (ESC) by sputtering. The wetting layer 54 (tin) is applied to a backside surface of the substrate 50 (aluminum) by ultrasonic wetting. Ultrasonic wetting means that a thin layer of molten tin is spread uniformly over the surface of the substrate 50 using a tool that delivers ultrasonic energy while the molten tin is being spread. The wetting layer 54 can also be applied by sputtering or plating.

After the wetting layer 54 has solidified, the debonding layer 46 is applied on top of the wetting layer 54 by heating the substrate 50 to a temperature above the melting point of tin (approximately 232° C.). Molten tin is then spread over the wetting layer 54 to form a thin layer of tin, preferably having a thickness of approximately 0.001 inches (0.254 mm). Excess tin is removed by wiping the excess molten tin away. Alternatively, excess tin that has solidified may be removed by machining the excess tin away.

After the debonding layer 46 has been formed on the substrate 50, the elastomer layer 42 is formed using a procedure that is analogous to the procedure described previously with respect to the elastomer layer 22 in item 10. Specifically, the surfaces of the metallization layer 38 and the debonding layer 46 that will be in contact with the elastomer layer 42 are primed to promote adhesion, such as by coating the surfaces with Dow Coming Primer 1200 or a similar chemical. A piece of copper mesh is also primed, for example by coating the surface of the copper mesh with Dow Coming Primer 1200 or a similar chemical.

After the recommended wait time for allowing the primer to dry, the Sylgard® 184is mixed according to the manufacturer's instructions. Aluminum powder filler is added to the elastomer in a ratio of 1:1 by weight of the A component of elastomer (Sygarde® 184). The elastomer/aluminum powder mixture is thoroughly mixed and degassed and the elastomer mixture is applied uniformly to the surfaces of the metallization layer 38 and the debonding layer 46.

The piece of primed copper mesh is then placed on the elastomer that is covering the debonding layer 46. The substrate 34 is placed on the substrate 50 with the elastomer coated on the metallization layer 38 being brought into contact with the elastomer coated on the debonding layer 46. Pressure is applied to the substrate 34 to hold the item 30 together while the elastomer cures, such as by applying four pounds per square inch (PSI) on the substrate 34, either by weight or clamping. Heat is then applied to the item 10 to cure the elastomer. After the elastomer has cured, the pressure is removed and the elastomer bond is sufficiently strong to hold the item 30 together without the use of other attachment means, such as mechanical fasteners.

In one embodiment, the present invention is an item (such as the item 30) comprised of a first substrate (such as the substrate 34); a metallization layer (such as the metallization layer 38) adhered to a surface of the first substrate; an elastomer layer (such as the elastomer layer 42) positioned adjacent to the metallization layer; a second substrate (such as the substrate 50); and a debonding layer (such as the debonding layer 46) positioned between the elastomer layer and the second substrate. The debonding layer is comprised of a material that melts at a temperature that will not result in damage to the first substrate and/or the second substrate. The first substrate and the second substrate are held together by the elastomer layer and the debonding layer without the use of other attachment means, such as mechanical fasteners. Preferred types of elastomers that can be used in the elastomer layer include silicone elastomers and poly(dimethylsiloxane) elastomers. Other types of elastomers that can be used in the elastomer layer are the fluoroelastomers referred to as FKMs and the perfluoroelastomers referred to as FFKMs.

In another embodiment, the item 30 can comprise the components listed in the paragraph above and also include a wetting or metallization layer, such as the layer 54, positioned between the second substrate and the debonding layer. In another embodiment, the item 30 can comprise the components listed in the paragraph above but without the metallization layer 38. Such an embodiment could also include the wetting layer 54. The metallization layer 38 could be deleted in cases where the substrate 34 and the elastomer layer 42 form an acceptable bond to each other.

A method for using the invention described above comprises debonding an item (such as the item 30) by heating the item comprised of a first substrate (such as the substrate 34); a metallization layer (such as the metallization layer 38) adhered to a surface of the first substrate; an elastomer layer (such as the elastomer layer 42) positioned adjacent to the metallization layer; a second substrate (such as the substrate 50); and a debonding layer (such as the debonding layer 46) positioned between the elastomer layer and the second substrate until the debonding layer softens; and then separating the first substrate from the second substrate.

Preferably, the separation occurs at the site of the debonding layer, although it doesn't matter whether the debonding layer separates from the elastomer layer 42 or from the second substrate. Also, preferably, the temperature to which the item is heated to cause debonding is less than 250° C., and more preferably is less than or equal to 232° C. Generally, the item is heated to the melting point of the debonding layer to cause the first and second substrates to become separated. However, the first and second substrates can be separated whenever the debonding layer softens sufficiently, even if this is a few degrees (e.g. 1-3° C.) lower than the melting point. Preferably, the debonding layer comprises a solder material selected from the group consisting of indium, tin, bismuth and alloys of indium, tin or bismuth. Pure bismuth has a melting point of approximately 271° C. which is slightly above the preferred maximum of 250° C. However, in some situations, such as where the slightly higher temperature will not damage the first substrate and/or the second Io substrate, a material that melts slightly above 250° C. (e.g. bismuth) can be used as the debonding layer. Furthermore, alloys of bismuth melt at temperatures lower than 250° C.

Although the present invention has been described in terms of the presently preferred embodiments, it is to be understood that such disclosure is not to be interpreted as limiting. Various alterations and modifications will no doubt become apparent to those skilled in the art after having read the above disclosure. Accordingly, it is intended that the appended claims be interpreted as covering all alterations and modifications as fall within the true scope of the invention.

We claim:

1. An apparatus comprising:
a first substrate;
a metallization layer adhered to a surface of the first substrate;
a second substrate; and
an elastomer layer positioned between the metallization layer and the second substrate, with the elastomer layer being sufficiently strong to hold the first substrate and the second substrate together without the need for additional attachment means to hold the first substrate and the second substrate together.

2. The apparatus of claim I wherein the first substrate comprises gold.

3. The apparatus of claim 1 wherein the metallization layer comprises titanium.

4. The apparatus of claim I wherein the elastomer layer comprises a PDMS elastomer.

5. The apparatus of claim 1 wherein the first substrate comprises a sputtering target comprised of gold, the metallization layer comprises titanium and aluminum, and the elastomer layer comprises a PDMS elastomer.

6. An apparatus comprising:
a first substrate;
a metallization layer adhered to a surface of the first substrate;
a second substrate;
an elastomer layer positioned adjacent to the metallization layer, with the elastomer layer being sufficiently strong to hold the first substrate and the second substrate together without the need for additional attachment means to hold the first substrate and the second substrate together; and
a debonding layer positioned between the elastomer layer and the second substrate, with the debonding layer melting at a temperature that will not result in damage to the first substrate.

7. The apparatus of claim 6 wherein the debonding layer comprises a material that melts in the temperature range of 75 to 250° C.

8. The apparatus of claim 6 wherein the debonding layer comprises a material selected from the group consisting of indium, tin, bismuth and alloys of indium, tin or bismuth.

9. The apparatus of claim 6 wherein the elastomer layer comprises a PDMS elastomer.

10. The apparatus of claim 6 wherein the first substrate comprises a ceramic material.

11. The apparatus of claim 6 wherein the metallization layer comprises titanium.

12. The apparatus of claim 6 further comprising a wetting layer positioned between the debonding layer and the second substrate for helping the debonding layer adhere to the second substrate.

13. A method for separating a first substrate from a second substrate comprising:
heating an item comprised of a first substrate, a metallization layer adhered to a surface of the first substrate, an elastomer layer positioned adjacent to the metallization layer, a second substrate and a debonding layer positioned between the elastomer layer and the second substrate until the debonding layer softens; and
separating the second substrate from the first substrate.

14. The method of claim 13 wherein the debonding layer has a melting point in the range of 75 to 250° C.

15. The method of claim 14 wherein the item is heated to the melting point of the debonding layer.

16. The method of claim 13 wherein the debonding layer comprises a solder material selected from the group consisting of indium, tin, bismuth and alloys of indium, tin or bismuth.
